(19) United States
(12) Patent Application Publication
(10) Pub. No.: US 2024/0395588 A1
(43) Pub. Date: Nov. 28, 2024

(54) EXHAUST DEVICE

(71) Applicant: Taiwan Semiconductor Manufacturing Company Limited, Hsin-Chu (TW)

(72) Inventors: Chien-Liang CHEN, New Taipei City (TW); Cheng-Feng YANG, Tainan City (TW); Shao-Chien HSU, Hsinchu City (TW); Song-Ting HUANG, Tainan City (TW)

(21) Appl. No.: 18/412,736

(22) Filed: Jan. 15, 2024

Related U.S. Application Data
(60) Provisional application No. 63/469,348, filed on May 26, 2023.

(51) Int. Cl. H01L 21/673

(52) U.S. Cl. CPC H01L 21/67389

(57) ABSTRACT

An apparatus is provided. The apparatus includes a wafer storage device having an inlet through which a gas flows into a wafer storage chamber of the wafer storage device. A first portion of the gas exits the wafer storage chamber of the wafer storage device through an outlet of the wafer storage device. A second portion of the gas exits the wafer storage chamber of the wafer storage device through one or more discontinuities of the wafer storage device to a space external to the wafer storage device. The apparatus includes an exhaust device arranged relative to the wafer storage device to conduct a measure of the second portion of the gas away from the space.

### RELATED APPLICATION

This application claims priority to U.S. provisional application 63/469,348, titled “EXHAUST STRUCTURE FOR MINI-ENVIRONMENT AIRBORNE MOLECULAR CONTAMINATION (AMC)/MOISTURE/OXYGEN IMPROVEMENT” and filed on May 26, 2023, which is incorporated herein by reference.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer. The semiconductor wafer is transferred to stations used to perform the one or more semiconductor fabrication processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a wafer storage device, in accordance with some embodiments.

FIG. 2A illustrates a side view of an apparatus, in accordance with some embodiments.

FIG. 2B illustrates a top view of an apparatus, in accordance with some embodiments.

FIG. 3A illustrates an exploded view of an exhaust device, in accordance with some embodiments.

FIG. 3B illustrates a perspective view of an exhaust device, in accordance with some embodiments.

FIG. 3C illustrates a ceiling of an exhaust device, in accordance with some embodiments.

FIG. 3D illustrates a wall of an exhaust device, in accordance with some embodiments.

FIG. 3E illustrates a wall of an exhaust device, in accordance with some embodiments.

FIG. 3F illustrates a perspective view of an exhaust device, in accordance with some embodiments.

FIG. 3G illustrates a wall of an exhaust device, in accordance with some embodiments.

FIG. 3H illustrates a perspective view of an exhaust device, in accordance with some embodiments.

FIG. 4 illustrates a side view of a processing station, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

Semiconductor wafers are subjected to various processes in various processing stations during the fabrication of semiconductor devices. In some embodiments, the semiconductor wafers are transported and temporarily stored in wafer storage devices, which may also be referred to as carriers. In some embodiments, a wafer storage device provides a humidity and contamination controlled environment to maintain the integrity of semiconductor wafers stored in the wafer storage device. In some embodiments, a purge process is performed to introduce a purge gas into a wafer storage chamber of the wafer storage device to reduce at least one of moisture, an oxygen level, an amount of pollutants, etc. in the wafer storage chamber. In some embodiments, at least some of the purge gas escapes the wafer storage chamber into a space external to the wafer storage device through one or more discontinuities of the wafer storage device. In accordance with some embodiments of the present disclosure, an exhaust device is arranged relative to the wafer storage device to conduct a measure of the escaped gas away from the space, thereby providing for at least one of airborne molecular contamination (AMC) reduction in the space, improved air quality of the space, improved conditions and/or reduced health risks for humans exposed to the space, reduced contamination to equipment in the space, etc.

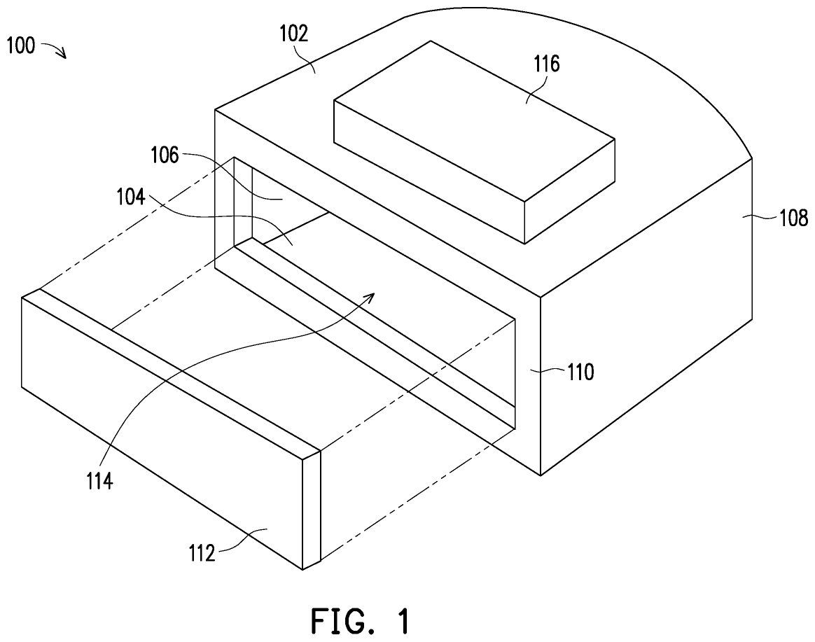

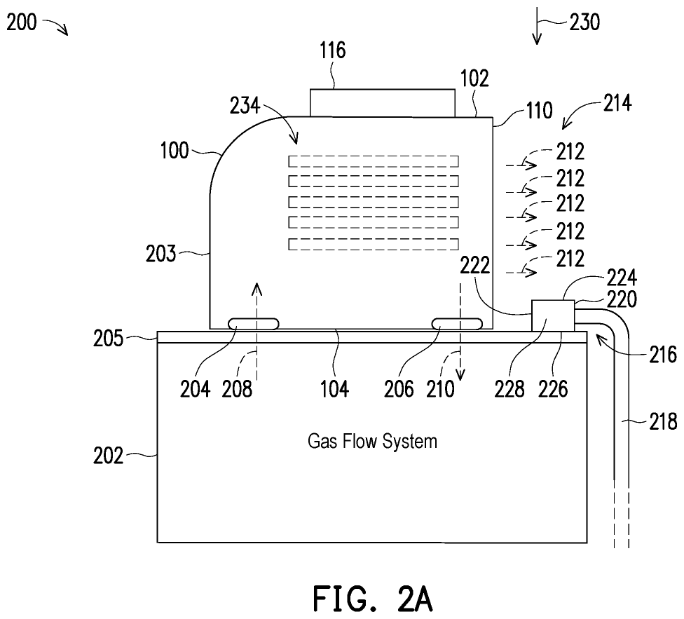

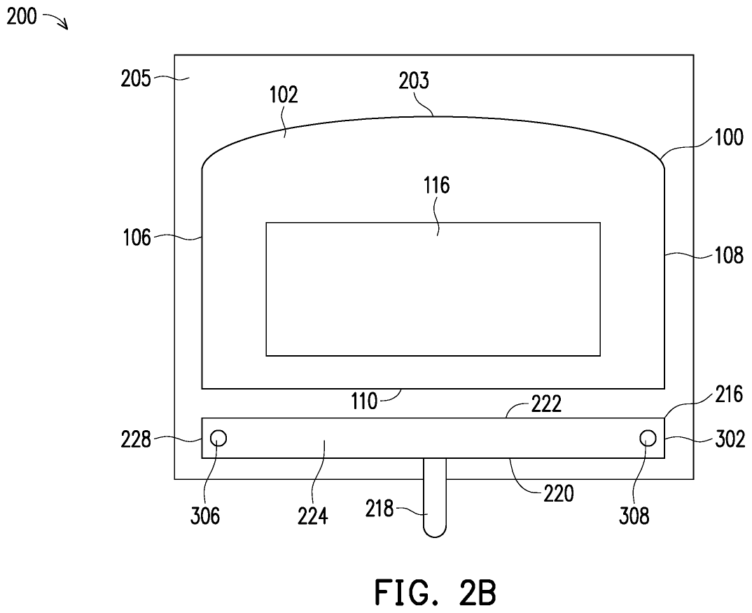

FIG. 1 illustrates a perspective view of a wafer storage device 100 according to some embodiments. In some embodiments, the wafer storage device 100 is disposed in a semiconductor manufacturing environment 412, such as in a facility, a room, etc. with one or more semiconductor processing stations. In some embodiments, the wafer storage device 100 comprises at least one of a front opening unified pod (FOUP), a cassette pod, a reticle pod, or other type of wafer storage device. The wafer storage device 100 comprises at least one of a first floor 104, a first ceiling 102, or one or more first walls between the first floor 104 and the first ceiling 102. The one or more first walls comprise at least one of a first wall 106, a second wall 108 opposing the first wall 106, a third wall 110 and a fourth wall 203 (shown in FIGS. 2A-2B) opposing the third wall 110. In some embodiments, the third wall 110 corresponds to a front side of the wafer storage device 100 and the fourth wall 203 corresponds to a back side of the wafer storage device 100. In some embodiments, the fourth wall 203 is curved. At least one of the first floor 104, the first ceiling 102, or the one or more first walls define a wafer storage chamber 114 for storage of one or more semiconductor wafers 234 (shown as dashed-line rectangles in FIG. 2A).

In some embodiments, the one or more semiconductor wafers 234 comprise a batch of wafers. In some embodiments, the one or more semiconductor wafers 234 comprise at least one of one or more substrates, one or more photomasks, one or more semiconductor devices, one or more dies, etc. In some embodiments, the one or more semiconductor wafers 234 are stacked vertically in the wafer storage device 100. In some embodiments, the one or more semiconductor wafers 234 are supported by a support frame, of the wafer storage device 100, having at least one of wafer shelves or wafer slots. In some embodiments, a semiconductor wafer stored in the wafer storage device 100 comprises one or more layers, such as at least one of a semiconductor layer, a conductor layer, or an insulator layer. In some embodiments, the one or more semiconductor wafers 234 are subjected to different processes using different processing stations during fabrication of one or more semiconductor devices. In some embodiments, the one or more semiconductor wafers 234 are transported and temporarily stored in batches in the wafer storage device 100 and/or one or more other wafer storage devices, during intervals between the different processes.

In some embodiments, the wafer storage device 100 comprises a handle 116 that enables the wafer storage device 100 to be at least one of held or repositioned by at least one of a person or machinery such as a robot. In some embodiments, the handle 116 is coupled to the first ceiling 102 of the wafer storage device 100. The third wall 110 defines an opening exposing the wafer storage chamber 114. In some embodiments, the wafer storage device 100 comprises a door 112, fitted to the opening, to provide ingress and egress to the wafer storage chamber 114. In some embodiments, the door 112 is open and a semiconductor wafer is inserted into the wafer storage chamber 114 through the opening. In some embodiments, the door 112 is closed and the semiconductor wafer is sealed within the wafer storage chamber 114 by the door 112. In some embodiments, the wafer storage device 100 comprises a transparent material so that the state of the wafer inside the wafer storage chamber 114 is observable from outside the wafer storage device 100. The wafer storage device 100 comprises at least one of plastic or tempered glass. Other materials of the wafer storage device 100 are within the scope of the present disclosure.

FIGS. 2A-2B illustrate aspects of an apparatus 200, according to some embodiments. FIG. 2A illustrates a side view of an apparatus 200 comprising at least one of the wafer storage device 100, a gas flow system 202, or an exhaust device 216, according to some embodiments. FIG. 2B illustrates a top view of the apparatus 200, according to some embodiments. In some embodiments, the wafer storage device 100 comprises at least one of an inlet 204, such as a gas inlet, or an outlet 206, such as a gas outlet. In some embodiments, at least one of the inlet 204 or the outlet 206 comprise an opening through the first floor 104 of the wafer storage device 100. In some embodiments, the inlet 204 defines at least one of an opening, a pathway, a port, etc. through which a gas enters the wafer storage chamber 114 of the wafer storage device 100. In some embodiments, the outlet 206 defines at least one of an opening, a pathway, a port, etc. through which a gas exits the wafer storage chamber 114 of the wafer storage device 100. In some embodiments, the apparatus 200 comprises a platform 205 on which at least one of the wafer storage device 100 or the exhaust device 216 are disposed. In some embodiments, a processing station, such as a load port of the processing station, comprises the platform 205.

In some embodiments, at least one of the wafer storage device 100 or the one or more semiconductor wafers 234 stored in the wafer storage device 100 are subjected to a gas flow process. In some embodiments, the gas flow process comprises using the gas flow system 202 to conduct a first gas 208 through the inlet 204 into the wafer storage chamber 114 of the wafer storage device 100. In some embodiments, the gas flow system 202 comprises one or more first components (not shown) that are at least one of coupled to the inlet 204 or used to conduct the first gas 208 from a gas source to the inlet 204. In some embodiments, the one or more first components comprise at least one of a gas conduit, a pump, etc. In some embodiments, at least one of the gas flow process is a purge process, the first gas 208 is a purge gas, or the gas flow system 202 comprises a purge system. In some embodiments, the first gas 208 comprises at least one of nitrogen (N₂), clean dry air (CDA), or other suitable gas. In some embodiments, the CDA comprises extreme clean dry air (XCDA). In some embodiments, the gas flow process is performed to at least one of (i) reduce particle concentration in the wafer storage chamber 114, (ii) reduce a humidity level in the wafer storage chamber 114, (iii) remove pollutants, such as at least one of airborne molecular contamination (AMC), gaseous chemical pollutants, or other unwanted particles, from the wafer storage chamber 114, (iv) improve a cleanliness and/or maintain the cleanliness of the one or more semiconductor wafers 234 stored in the wafer storage device 100, (v) improve a cleanliness and/or maintain the cleanliness of one or more parts of the wafer storage device 100, such as one or more inner surfaces defining the wafer storage chamber 114, (vi) reduce an oxygen level in the wafer storage chamber 114, (vii) reduce a total volatile organic compound (TVOC) level in the wafer storage chamber 114, or (viii) provide for one or more other suitable impacts on the wafer storage device 100 and/or the one or more semiconductor wafers 234 stored in the wafer storage device 100.

In some embodiments, upon completion of the gas flow process, the humidity level in the wafer storage chamber 114 is less than a threshold humidity level. The threshold humidity level is about 10% relative humidity (RH). Relative humidity corresponds to a proportion of absolute humidity in an environment to a saturated absolute humidity at a same temperature and a same pressure. Other values of the threshold humidity level are within the scope of the present disclosure. In some embodiments, upon completion of the gas flow process, the oxygen level in the wafer storage chamber 114 is less than a threshold oxygen level. The threshold oxygen level is about 1%. Other values of the threshold oxygen level are within the scope of the present disclosure. In some embodiments, upon completion of the gas flow process, the TVOC level in the wafer storage chamber 114 is less than a threshold TVOC level. The threshold TVOC level is about 10 micrograms per cubic meter (μg/m³). Other values of the threshold TVOC level are within the scope of the present disclosure.

In some embodiments, the gas flow system 202 is arranged relative to the wafer storage device 100 such that after the first gas 208 is conducted into the wafer storage chamber of the wafer storage device 100, at least one of (i) a first portion of the first gas 208 exits the wafer storage chamber 114 through the outlet 206, or (ii) a second portion of the first gas 208 exits the wafer storage chamber 114 through one or more first discontinuities of the wafer storage device 100 to a space 214 external to the wafer storage device 100. In some embodiments, not all of the first gas 208 exits the wafer storage chamber 114 through the outlet 206 since the wafer storage chamber 114 is not airtight, such as due, at least in part, to the one or more first discontinuities of the wafer storage device 100. In some embodiments, a discontinuity of the one or more first discontinuities corresponds an opening through which a gas can leak out of the wafer storage chamber 114, such as at least one of a hole, a puncture, a slit, etc. In some embodiments, the one or more first discontinuities may comprise at least one of (i) one or more discontinuities in the first wall 106, (ii) one or more discontinuities in the second wall 108, (iii) one or more discontinuities in the third wall 110, (iv) one or more discontinuities in the fourth wall 203, (v) one or more discontinuities in the first ceiling 102, (vi) one or more discontinuities in the first floor 104, (vii) one or more discontinuities at an interface of two walls of the wafer storage device 100, (viii) one or more discontinuities at an interface of a wall of the wafer storage device 100 and the first ceiling 102, (ix) one or more discontinuities at an interface of a wall of the wafer storage device 100 and the first floor 104, (x) a discontinuity between the door 112 of the wafer storage device 100 and the third wall 110 of the wafer storage device 100, such as when the door 112 of the wafer storage device 100 is at least partially open, or (xi) one or more other discontinuities. In some embodiments, the door 112 of the wafer storage device 100 is at least partially open, such as propped open, to allow at least some of the second portion of the first gas 208 to exit the wafer storage chamber 114 through the discontinuity between the door 112 of the wafer storage device 100 and the third wall 110 of the wafer storage device 100.

In some embodiments, during the gas flow process, a first expelled gas is expelled from the wafer storage chamber 114 by the gas flow process. In some embodiments, the first expelled gas comprises at least one of one or more corrosive gases, one or more pollutants, AMC, gaseous chemical pollutants, volatile organic compounds, ammonia (NH₃), acetone, alkanes, aromatics, alkenes, halogenated hydrocarbons, esters, aldehydes, ketones, or one or more other gases and/or particles. In some embodiments, the one or more semiconductor wafers 234 are etched using one or more etching gases and/or one or more etching products prior to the gas flow process. In some embodiments, the first expelled gas comprises the one or more etching gases and/or the one or more etching products. In some embodiments, the one or more etching gases comprise at least one of CxHyFz (where x, y, z: 0˜6), He, Ar, F₂, Cl₂, O₂, N₂, H₂, HBr, HF, NF₃, SF₆, or other suitable etching gas. In some embodiments, the one or more etching products comprise at least one of FCN, COₓ (x: 1˜2), SiClₓ (where x: 1˜4), SiFₓ (where x: 1˜4), or other suitable etching product. In some embodiments, the first expelled gas is comprised within the wafer storage chamber 114 prior to the gas flow process and is expelled from the wafer storage chamber 114 using the gas flow process. In some embodiments, if the first expelled gas is not expelled from the wafer storage chamber 114, the first expelled gas can induce at least one of (i) oxidation of the one or more semiconductor wafers 234 stored in the wafer storage chamber 114, (ii) a loss of one or more metals of the one or more semiconductor wafers 234, (iii) a defect in a wafer of the one or more semiconductor wafers 234, or (iv) other unwanted chemical reaction with the one or more semiconductor wafers 234. Thus, in accordance with some embodiments, performing the gas flow process to expel the first expelled gas from the wafer storage chamber 114 at least one of improves an integrity of the one or more semiconductor wafers 234, mitigates particle-induced defects to the one or more semiconductor wafers 234, or mitigates chemical reactions that could damage the one or more semiconductor wafers 234.

In some embodiments, a second gas 210 exits the wafer storage chamber 114 through the outlet 206. In some embodiments, the second gas 210 exits the wafer storage chamber 114 during the gas flow process. In some embodiments, the second gas 210 comprises at least one of the first portion of the first gas 208 or a first portion of the first expelled gas. In some embodiments, the gas flow system 202 comprises one or more second components (not shown) that are at least one of coupled to the outlet 206 or used to conduct the second gas 210 from the outlet 206 to at least one of a location external to the space 214, a gas storage device, etc. In some embodiments, the one or more second components comprise at least one of a gas conduit, a pump, etc. In some embodiments, a first flow rate of the first gas 208 flowing through the inlet 204 of the wafer storage device 100 is greater than a second flow rate of the second gas 210 flowing through the outlet 206 of the wafer storage device 100.

In some embodiments, a third gas 212 exits the wafer storage chamber 114 through the one or more first discontinuities to the space 214 external to the wafer storage device 100. In some embodiments, the third gas 212 exits the wafer storage chamber 114 during the gas flow process. In some embodiments, the third gas 212 comprises at least one of the second portion of the first gas 208 or a second portion of the first expelled gas.

In some embodiments, the exhaust device 216 is arranged relative to the wafer storage device 100 to conduct a measure of the third gas 212 (comprising at least one of the second portion of the first gas 208 or the second portion of the first expelled gas) away from the space 214. In some embodiments, the measure of the third gas 212 comprises a portion of the third gas 212. In some embodiments, the measure of the third gas 212 comprises all of the third gas 212. In some embodiments, the measure of the third gas 212 comprises at least a threshold proportion of the third gas 212. The threshold proportion of the third gas 212 is between about 50% of the third gas 212 to about 99% of the third gas 212. Other values of the threshold proportion of the third gas 212 are within the scope of the present disclosure.

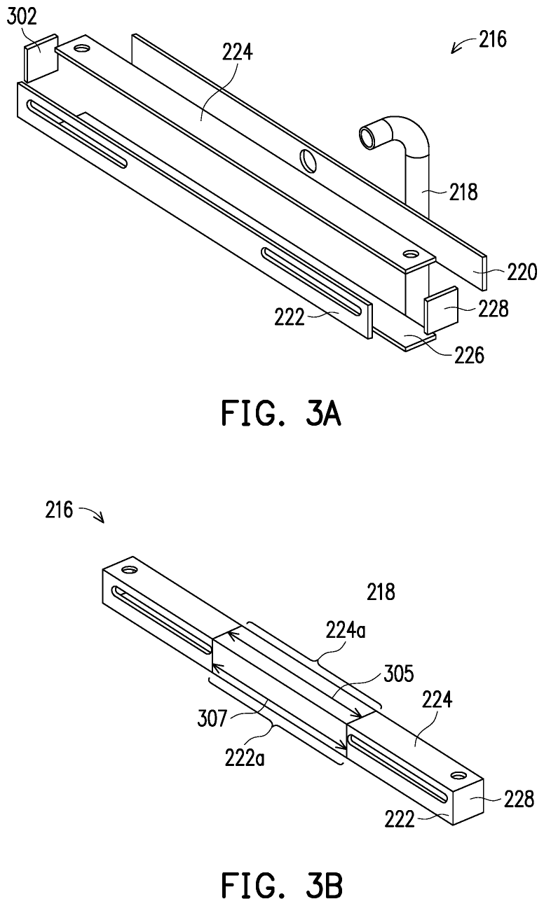

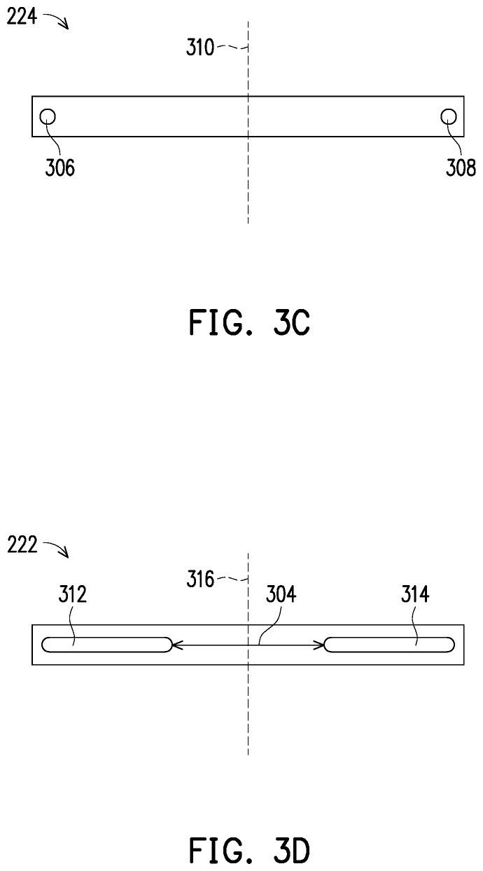

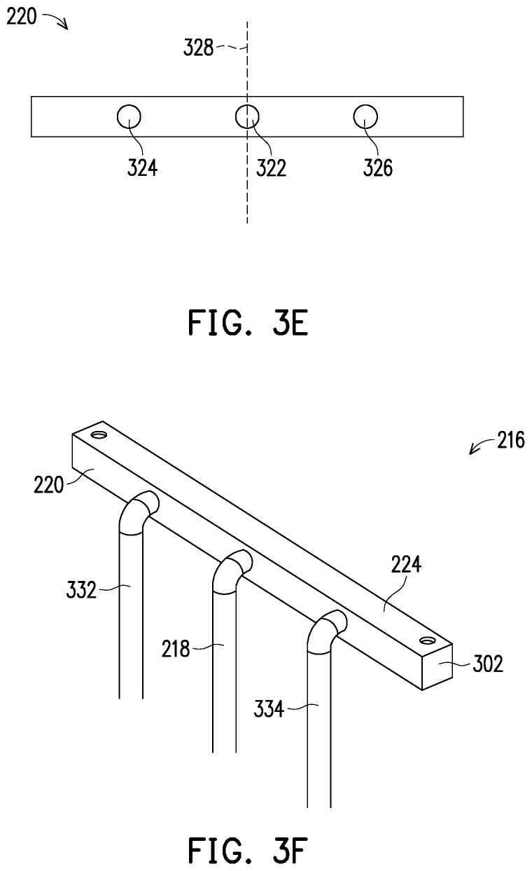

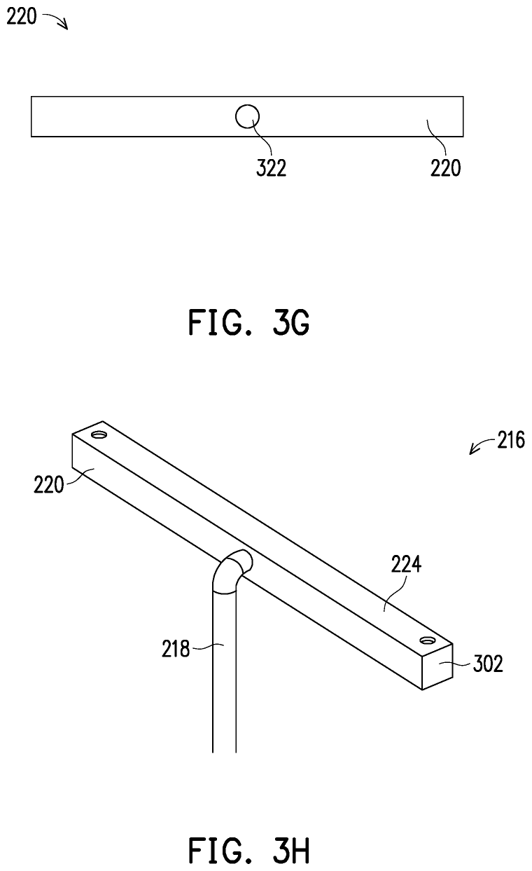

In some embodiments, the exhaust device 216 comprises at least one of a second floor 226, a second ceiling 224, or one or more second walls between the second floor 226 and the second ceiling 224. The one or more second walls comprise at least one of a fifth wall 222, a sixth wall 220 opposing the fifth wall 222, a seventh wall 228 and an eighth wall 302 (shown in FIG. 3A) opposing the seventh wall 228. At least one of the second floor 226, the second ceiling 224, or the one or more second walls define an exhaust chamber into which the measure of the third gas 212 is conducted. In some embodiments, the exhaust device 216 comprises a first gas conduit 218. In some embodiments, the first gas conduit 218 is connected to the sixth wall 220. In some embodiments, the first gas conduit 218 is configured to conduct the measure of the third gas 212 out of the exhaust chamber. In some embodiments, the first gas conduit 218 is configured to conduct the measure of the third gas 212 to at least one of a location external to the space 214, a gas storage device, or to other suitable location.

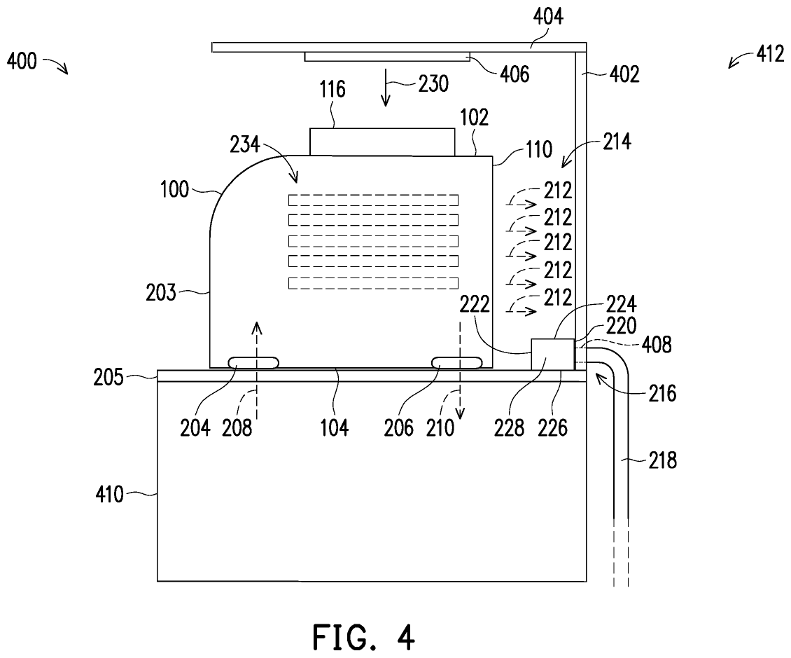

In some embodiments, the apparatus 200 comprises a gas circulation device 406 (shown in FIG. 4) configured to circulate a fourth gas in a direction 230 (shown in FIG. 2A), such as a downwards direction. In some embodiments, downward flow of the fourth gas promotes flow of the third gas 212 into the exhaust chamber. In some embodiments, downward flow of the fourth gas funnels the third gas 212 into the exhaust chamber. In some embodiments, circulating the fourth gas in the direction 230 provides for improved performance of the exhaust device 216 and/or an increase of the measure of the third gas 212 that is conducted away from the space 214 as compared to an embodiment in which the fourth gas is not circulated in the direction 230.

In some embodiments, the third gas 212 comprises at least one of one or more corrosive gases, one or more pollutants, AMC, gaseous chemical pollutants, volatile organic compounds, ammonia (NH₃), acetone, alkanes, aromatics, alkenes, halogenated hydrocarbons, esters, aldehydes, ketones, one or more etching gases, one or more etching products, or one or more other gases and/or particles. Thus, in accordance with some embodiments, using the exhaust device 216 to conduct the measure of the third gas 212 away from the space 214 provides for at least one of AMC reduction in the space 214, improved air quality of the space 214, improved conditions and/or reduced health risks for humans exposed to the space 214, reduced contamination to equipment in the space 214, etc. In some embodiments, using the exhaust device 216 to conduct the measure of the third gas 212 away from the space 214 allows the gas flow system 202 to at least one of increase an amount of the first gas 208 used to perform the gas flow process or increase a flow rate of the gas flow process, thereby providing for at least one of increased speed with which the gas flow process is performed, improved performance of the gas flow process, quicker and/or increased production of semiconductor wafers, etc.

FIGS. 3A-3G illustrate aspects of the exhaust device 216 according to some embodiments. FIG. 3A illustrates an exploded view of the exhaust device 216, according to some embodiments. FIG. 3B illustrates a perspective view of the exhaust device 216, according to some embodiments. In some embodiments, the fifth wall 222 of the exhaust device 216 is arranged relative to the wafer storage device 100 to face at least one of the third wall 110 of the wafer storage device 100 or the door 112 of the wafer storage device 100.

FIG. 3C illustrates the second ceiling 224 of the exhaust device 216, according to some embodiments. In some embodiments, the second ceiling 224 defines one or more first openings. In some embodiments, each opening of one, some, and/or all of the one or more first openings has a first size. In some embodiments, the first size corresponds to a first area. The first area is less than about 300 square centimeters. Other values of the first area are within the scope of the present disclosure. In some embodiments, each opening of one, some and/or all of the one or more first openings has a size, such as an area, that is within a first range of sizes, such as a first range of areas. In some embodiments, the first range of sizes ranges from a first minimum size to a first maximum size. In some embodiments, the first maximum size is about 300 square centimeters. In some embodiments, each opening of one, some, and/or all of the one or more first openings is at least one of (i) circular, (ii) elliptical, (iii) rectangular, (iv) rectangular with curved corners, (v) square-shaped, (vi) square-shaped with curved corners, or (vii) other shape. In some embodiments, the one or more first openings comprise a first opening 306 and a second opening 308. Although FIG. 3C illustrates the second ceiling 224 having two openings, embodiments are contemplated in which the second ceiling 224 has any other number of openings. In some embodiments, the one or more first openings are arranged symmetrically about an axis 310. In some embodiments, the axis 310 extends through a center of the second ceiling 224.

FIG. 3D illustrates the fifth wall 222 of the exhaust device 216, according to some embodiments. In some embodiments, the fifth wall 222 defines one or more second openings. In some embodiments, each opening of one, some, and/or all of the one or more second openings has a second size. In some embodiments, the second size corresponds to a second area. The second area is less than about 500 square centimeters. Other values of the second area are within the scope of the present disclosure. In some embodiments, each opening of one, some and/or all of the one or more second openings has a size, such as an area, that is within a second range of sizes, such as a second range of areas. In some embodiments, the second range of sizes ranges from a second minimum size to a second maximum size. In some embodiments, the second maximum size is about 500 square centimeters. In some embodiments, each opening of one, some, and/or all of the one or more second openings is at least one of (i) circular, (ii) elliptical, (iii) rectangular, (iv) rectangular with curved corners, (v) square-shaped, (vi) square-shaped with curved corners, or (vii) other shape. In some embodiments, the one or more second openings comprise a third opening 312 and a fourth opening 314. Although FIG. 3D illustrates the fifth wall 222 having two openings, embodiments are contemplated in which the fifth wall 222 has any other number of openings. In some embodiments, the one or more second openings are arranged symmetrically about an axis 316. In some embodiments, the axis 316 extends through a center of the fifth wall 222.

In some embodiments, a distance 304 between the third opening 312 and the fourth opening 314 is less than a first threshold distance. The first threshold distance is between about 50 centimeters and about 150 centimeters (and/or the first threshold distance is about 100 centimeters). Other values of the first threshold distance are within the scope of the present disclosure. In some embodiments, the distance 304 being less than the first threshold distance provides for improved performance of the exhaust device 216 and/or an increase of the measure of the third gas 212 that is conducted away from the space 214 as compared to an embodiment in which the distance 304 is not less than the first threshold distance. In some embodiments, the distance 304 is within a first range of distances. The first range of distances ranges from about 1 centimeter to about 150 centimeters (and/or from about 5 centimeters to about 100 centimeters). Other values of the first range of distances are within the scope of the present disclosure. In some embodiments, the distance 304 being within the first range of distances provides for improved performance of the exhaust device 216 and/or provides for an increase of the measure of the third gas 212 that is conducted away from the space 214 as compared to an embodiment in which the distance 304 is not within the first range of distances.

In some embodiments, the fifth wall 222 is a gas entry wall configured such that at least some of the measure of the third gas 212 flows through the one or more second openings into the exhaust chamber. In some embodiments, the second ceiling 224 is a gas entry ceiling configured such that at least some of the measure of the third gas 212 flows through the one or more first openings into the exhaust chamber.

In some embodiments, the second size associated with the one or more second openings defined by the fifth wall 222 is greater than the first size associated with the one or more first openings defined by the second ceiling 224. In some embodiments, the second size being greater than the first size provides for improved performance of the exhaust device 216 and/or provides for an increase of the measure of the third gas 212 that is conducted away from the space 214 as compared to an embodiment in which the second size is not greater than the first size. In some embodiments, the second minimum size of the second range of sizes associated with the one or more second openings defined by the fifth wall 222 is greater than the first maximum size of the first range of sizes associated with the one or more first openings defined by the second ceiling 224. In some embodiments, the second minimum size being greater than the first maximum size provides for improved performance of the exhaust device 216 and/or provides for an increase of the measure of the third gas 212 that is conducted away from the space 214 as compared to an embodiment in which the second minimum size is not greater than the first maximum size.

Referring back to FIG. 3B, in some embodiments, a portion 222a, of the fifth wall 222, between the third opening 312 and the fourth opening 314 does not define an opening of the one or more second openings. In some embodiments, the portion 222a of the fifth wall 222 does not define any opening through which a gas can flow to or from the exhaust chamber. In some embodiments, a portion 224a of the second ceiling 224 does not define an opening of the one or more first openings. In some embodiments, the portion 224a of the second ceiling 224 does not define any opening through which a gas can flow to or from the exhaust chamber. In some embodiments, the portion 224a of the second ceiling 224 is adjacent the portion 222a of the fifth wall 222. In some embodiments, a length 307 of the portion 222a is about equal to a length 305 of the portion 224a. In some embodiments, at least one of the length 307 of the portion 222a of the fifth wall 222 or the length 305 of the portion 224a of the second ceiling 224 is about equal to the distance 304 (shown in FIG. 3D) between the third opening 312 and the fourth opening 314. In some embodiments, the portion 224a of the second ceiling 224 not defining any openings provides for improved performance of the exhaust device 216 and/or provides for an increase of the measure of the third gas 212 that is conducted away from the space 214 as compared to an embodiment in which the portion 224a of the second ceiling 224 defines one or more openings. In some embodiments, the portion 222a of the fifth wall 222 not defining any openings provides for improved performance of the exhaust device 216 and/or provides for an increase of the measure of the third gas 212 that is conducted away from the space 214 as compared to an embodiment in which the portion 222a of the fifth wall 222 defines one or more openings.

FIG. 3E illustrates the sixth wall 220 of the exhaust device 216, according to some embodiments. In some embodiments, the sixth wall 220 defines one or more third openings. In some embodiments, the sixth wall 220 is a gas exit wall configured such that the measure of the third gas 212 flows out of the exhaust chamber through the one or more third openings. In some embodiments, each opening of one, some, and/or all of the one or more third openings is at least one of (i) circular, (ii) elliptical, (iii) rectangular, (iv) rectangular with curved corners, (v) square-shaped, (vi) square-shaped with curved corners, or (vii) other shape. In some embodiments, each opening of one, some, and/or all of the one or more third openings is configured to connect to a gas conduit used to conduct a gas out of the exhaust chamber. In some embodiments, the one or more third openings comprise at least one of a fifth opening 322, a sixth opening 324, or a seventh opening 326. Although FIG. 3E illustrates the sixth wall 220 having three openings, embodiments are contemplated in which the sixth wall 220 has any other number of openings. In some embodiments, the one or more third openings are arranged symmetrically about an axis 328. In some embodiments, the axis 328 extends through a center of the sixth wall 220.

FIG. 3F illustrates a perspective view of the exhaust device 216, according to some embodiments. In some embodiments, the exhaust device 216 comprises one or more gas conduits comprising at least one of the first gas conduit 218 connected to the fifth opening 322, a second gas conduit 332 connected to the sixth opening 324, or a third gas conduit 334 connected to the seventh opening 326. Although FIG. 3F illustrates the exhaust device 216 having three gas conduits, embodiments are contemplated in which the exhaust device 216 has any other number of gas conduits. In some embodiments, each gas conduit of one, some, and/or all of the one or more gas conduits is configured to conduct a gas out of the exhaust chamber. In some embodiments, each gas conduit of one, some, and/or all of the one or more gas conduits is configured to conduct at least some of the measure of the third gas 212 out of the exhaust chamber. A third flow rate of the measure of the third gas 212 conducted out of the exhaust chamber using the one or more gas conduits is between about 1 liter per minute (LPM) to about 1,000 LPM (and/or about 10 LPM to about 500 LPM). Other values of the third flow rate are within the scope of the present disclosure. In some embodiments, the apparatus 200 comprises one or more pumps (not shown) that are at least one of coupled to the one or more gas conduits or configured to conduct the third gas 212 through the one or more gas conduits.

FIG. 3G illustrates the sixth wall 220 of the exhaust device 216 according to some embodiments in which the one or more third openings comprises a single opening, such as the fifth opening 322. FIG. 3H illustrates a perspective view of the exhaust device 216, according to some embodiments in which the one or more gas conduits comprises a single gas conduit, such as the first gas conduit 218.

In some embodiments, the apparatus 200 comprises a processing station 400 configured to perform a semiconductor fabrication process on the one or more semiconductor wafers 234. FIG. 4 illustrates aspects of the processing station 400, according to some embodiments. In some embodiments, the processing station 400 comprises at least one of a station wall 402 or a station ceiling 404. In some embodiments, the station wall 402 comprises an opening 408 through which the first gas conduit 218 extends. In some embodiments, the processing station 400 comprises one or more station walls. In some embodiments, at least one of the station ceiling 404, the station wall 402, or the one or more station walls at least partially surround the wafer storage device 100. In some embodiments, the processing station 400 comprises the gas circulation device 406. In some embodiments, the gas circulation device 406 is coupled to the station ceiling 404. In some embodiments, the processing station 400 comprises a load port. In some embodiments, the load port comprises the platform 205. In some embodiments, the processing station 400 comprises a processing structure 410. In some embodiments, at least some components of the gas flow system 202, such as the purge system, are disposed in the processing structure 410. In some embodiments, the gas flow process, such as the purge process, is performed when the wafer storage device 100 is docked onto the load port.

In some embodiments, the processing station 400 comprises at least one of (i) chemical vapor deposition (CVD) equipment, (ii) physical vapor deposition (PVD) equipment, (iii) plating equipment, (iv) etching equipment, such as at least one of plasma etching equipment, wet etching equipment, dry etching equipment, reactive-ion etching (RIE) equipment, atomic layer etching (ALE) equipment, buffered oxide etching equipment, or ion beam milling equipment, (v) lithography equipment, (vi) chemical mechanical planarization (CMP) equipment, (vii) cleaning equipment, such as a cleaning tool comprising a cleaning tank in which a semiconductor wafer is at least one of washed, cleaned, etc., (viii) a furnace, such as a semiconductor furnace tool, or (ix) other equipment.

In some embodiments, a first semiconductor wafer of the one or more semiconductor wafers 234 stored in the wafer storage device 100 is transferred from the wafer storage device 100 into the processing station 400 via the load port of the processing station 400. In some embodiments, when the wafer storage device 100 is docked onto the load port, the first semiconductor wafer is unloaded from the wafer storage device 100 and inserted into the processing station 400. In some embodiments, after inserting the first semiconductor wafer into the processing station 400, the processing station 400 is used to perform the semiconductor fabrication process on the first semiconductor wafer to produce a first processed semiconductor wafer. In some embodiments, the semiconductor fabrication process comprises at least one of a PVD process, a plating process, an etching process, a lithography process, a CMP process, a CVD process, a thermal process, a cleaning process, or other process. In some embodiments, responsive to performing the first process on the first semiconductor wafer to produce the first processed semiconductor wafer, the first processed semiconductor wafer is removed from the processing station 400 and loaded into the wafer storage device 100. In some embodiments, multiple semiconductor wafers are processed using the processing station 400 at a time. In some embodiments, a single semiconductor wafer is processed using the processing station 400 at a time. In some embodiments, the processing station 400 is used to perform the first process on each semiconductor wafer of one, some or all semiconductor wafers stored in the wafer storage device 100 to produce a set of one or more processed semiconductor wafers, and the set of one or more processed semiconductor wafers are loaded into the wafer storage device 100. In some embodiments, the set of one or more processed semiconductor wafers comprises the first processed semiconductor wafer.

In some embodiments, the gas flow system 202 is configured to perform the gas flow process at least one of (i) while the one or more semiconductor wafers 234 are stored in the wafer storage device 100, or (ii) before the semiconductor fabrication process is performed on the one or more semiconductor wafers 234 to produce the set of one or more processed semiconductor wafers.

In some embodiments, the gas flow system 202 is configured to perform the gas flow process at least one of (i) while the set of one or more processed semiconductor wafers are stored in the wafer storage device 100, or (ii) after the semiconductor fabrication process is performed on the one or more semiconductor wafers 234 to produce the set of one or more processed semiconductor wafers.

In some embodiments, the semiconductor manufacturing environment is comprised within the space 214. In some embodiments, the first gas conduit 218 is configured to conduct the measure of the third gas 212 to a location external to the semiconductor manufacturing environment 412. Using the exhaust device 216 in accordance with some embodiments of the present disclosure provides for at least one of AMC reduction in the semiconductor manufacturing environment 412, improved air quality of the semiconductor manufacturing environment 412, improved conditions and/or reduced health risks for humans exposed to the semiconductor manufacturing environment 412, reduced contamination to equipment in the semiconductor manufacturing environment 412, improved semiconductor processing time, increased production, etc.

In some embodiments, an apparatus is provided. The apparatus includes a purge system configured to conduct a purge gas into a wafer storage chamber of a wafer storage device storing one or more semiconductor wafers. The purge system is arranged relative to the wafer storage device such that after the purge gas is conducted into the wafer storage chamber of the wafer storage device: (i) a first portion of the purge gas exits the wafer storage chamber of the wafer storage device through an outlet of the wafer storage device, and (ii) a second portion of the purge gas exits the wafer storage chamber of the wafer storage device through one or more discontinuities of the wafer storage device to a space external to the wafer storage device. The apparatus includes an exhaust device arranged relative the wafer storage device to conduct a measure of the second portion of the purge gas away from the space.

In some embodiments, an apparatus is provided. The apparatus includes a wafer storage device comprising an inlet through which a gas flows into a wafer storage chamber of the wafer storage device. A first portion of the gas exits the wafer storage chamber of the wafer storage device through an outlet of the wafer storage device. A second portion of the gas exits the wafer storage chamber of the wafer storage device through one or more discontinuities of the wafer storage device to a space external to the wafer storage device. The apparatus includes an exhaust device arranged relative to the wafer storage device to conduct a measure of the second portion of the gas away from the space.

In some embodiments, a processing station is provided. The processing station is configured to perform a semiconductor fabrication process on one or more semiconductor wafers stored in a wafer storage device. The processing station includes a load port. The processing station includes a purge system configured to conduct a purge gas into a wafer storage chamber of the wafer storage device when the wafer storage device is docked onto the load port. The purge system is arranged relative to the wafer storage device such that after the purge gas is conducted into the wafer storage chamber of the wafer storage device: (i) a first portion of the purge gas exits the wafer storage chamber of the wafer storage device through an outlet of the wafer storage device, and (ii) a second portion of the purge gas exits the wafer storage chamber of the wafer storage device through one or more discontinuities of the wafer storage device to a space external to the wafer storage device. The processing station includes an exhaust device arranged relative to the wafer storage device to conduct a measure of the second portion of the purge gas away from the space.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. An apparatus, comprising:
a purge system configured to conduct a purge gas into a wafer storage chamber of a wafer storage device storing one or more semiconductor wafers, wherein the purge system is arranged relative to the wafer storage device such that after the purge gas is conducted into the wafer storage chamber of the wafer storage device:
a first portion of the purge gas exits the wafer storage chamber of the wafer storage device through an outlet of the wafer storage device; and
a second portion of the purge gas exits the wafer storage chamber of the wafer storage device through one or more discontinuities of the wafer storage device to a space external to the wafer storage device; and
an exhaust device arranged relative the wafer storage device to conduct a measure of the second portion of the purge gas away from the space.

2. The apparatus of claim 1, wherein the exhaust device comprises:
a floor, a ceiling and one or more walls between the floor and the ceiling to define an exhaust chamber into which the measure of the second portion of the purge gas is conducted.

3. The apparatus of claim 2, wherein the one or more walls comprise:
a gas entry wall defining one or more first openings; and
a gas exit wall defining one or more second openings.

4. The apparatus of claim 3, wherein:
the gas entry wall is configured such that the measure of the second portion of the purge gas flows through the one or more first openings into the exhaust chamber; and
the gas exit wall is configured such that the measure of the second portion of the purge gas flows out of the exhaust chamber through the one or more second openings.

5. The apparatus of claim 2, wherein:
the ceiling defines one or more openings; and
the ceiling is configured such that the measure of the second portion of the purge gas flows through the one or more openings into the exhaust chamber.

6. The apparatus of claim 2, wherein the exhaust device comprises:
a gas conduit configured to conduct the measure of the second portion of the purge gas out of the exhaust chamber.

7. The apparatus of claim 6, wherein:
a semiconductor manufacturing environment is comprised within the space external to the wafer storage device; and
the gas conduit is configured to conduct the measure of the second portion of the purge gas to at least one of:
a location external to the semiconductor manufacturing environment; or
a gas storage device.

8. The apparatus of claim 1, wherein:
the purge gas comprises at least one of nitrogen or clean dry air (CDA).

9. An apparatus, comprising:
a wafer storage device comprising an inlet through which a gas flows into a wafer storage chamber of the wafer storage device, wherein:
a first portion of the gas exits the wafer storage chamber of the wafer storage device through an outlet of the wafer storage device; and
a second portion of the gas exits the wafer storage chamber of the wafer storage device through one or more discontinuities of the wafer storage device to a space external to the wafer storage device; and
an exhaust device arranged relative to the wafer storage device to conduct a measure of the second portion of the gas away from the space.

10. The apparatus of claim 9, wherein the exhaust device comprises:
a floor, a ceiling and one or more walls between the floor and the ceiling to define an exhaust chamber into which the measure of the second portion of the gas is conducted.

11. The apparatus of claim 10, wherein:
the one or more walls comprise:
a gas entry wall defining one or more first openings; and
a gas exit wall defining one or more second openings; and
the ceiling defines one or more third openings.

12. The apparatus of claim 11, wherein:
the gas entry wall and the ceiling are configured such that the measure of the second portion of the gas flows into the exhaust chamber through at least one of:
the one or more first openings; or
the one or more third openings; and
the gas exit wall is configured such that the measure of the second portion of the gas flows out of the exhaust chamber through the one or more second openings.

13. The apparatus of claim 12, wherein:
a first size of an opening of the one or more first openings defined by the gas entry wall is greater than a second size of an opening of the one or more third openings defined by the ceiling.

14. The apparatus of claim 10, wherein the exhaust device comprises:
a gas conduit configured to conduct the measure of the second portion of the gas out of the exhaust chamber.

15. The apparatus of claim 14, wherein:
a semiconductor manufacturing environment is comprised within the space external to the wafer storage device; and
the gas conduit is configured to conduct the measure of the second portion of the gas to at least one of:
a location external to the semiconductor manufacturing environment; or
a gas storage device.

16. The apparatus of claim 9, wherein:
the gas comprises at least one of nitrogen or clean dry air (CDA).

17. A processing station configured to perform a semiconductor fabrication process on one or more semiconductor wafers stored in a wafer storage device, the processing station comprising:
a load port;
a purge system configured to conduct a purge gas into a wafer storage chamber of the wafer storage device when the wafer storage device is docked onto the load port, wherein the purge system is arranged relative to the wafer storage device such that after the purge gas is conducted into the wafer storage chamber of the wafer storage device:
a first portion of the purge gas exits the wafer storage chamber of the wafer storage device through an outlet of the wafer storage device; and
a second portion of the purge gas exits the wafer storage chamber of the wafer storage device through one or more discontinuities of the wafer storage device to a space external to the wafer storage device; and
an exhaust device arranged relative to the wafer storage device to conduct a measure of the second portion of the purge gas away from the space.

18. The processing station of claim 17, wherein:
the purge system is configured to conduct the purge gas into the wafer storage chamber of the wafer storage device before the semiconductor fabrication process is performed on the one or more semiconductor wafers.

19. The processing station of claim 17, wherein:
the purge system is configured to conduct the purge gas into the wafer storage chamber of the wafer storage device after the semiconductor fabrication process is performed on the one or more semiconductor wafers.

20. The processing station of claim 17, wherein:
the purge gas comprises at least one of nitrogen or clean dry air (CDA).
